(19) United States
(12) Patent Application Publication
(10) Pub. No.: US 2014/0177171 A1
(43) Pub. Date: Jun. 26, 2014

(54) ELECTRICAL CONNECTION METHOD BETWEEN SERVER SYSTEM AND SERVER CABINET

(71) Applicant: HON HAI PRECISION INDUSTRY CO., LTD., New Taipei (TW)

(72) Inventor: CHIH-CHUNG SHIH, New Taipei (TW)

(21) Appl. No.: 13/940,274

(22) Filed: Jul. 12, 2013

(30) Foreign Application Priority Data
Dec. 24, 2012 (TW) 101149473

(51) Int. Cl. H05K 7/20

(52) U.S. Cl. CPC H05K 7/20736
USPC 361/695

(57) ABSTRACT

A server cabinet includes a rack assembly accommodating a number of servers, a number of fan groups, a first power source, and a second power source. The fan groups are coupled to a rear side of the rack assembly to provide horizontal airflow for dissipating heat generated by the number of servers. Each fan group includes a first fan and a second fan. The first power source is electrically connected to the first fan of each fan group, while the second power source is electrically connected to the second fan of each fan group.

### BACKGROUND

1. Technical Field

The present disclosure relates to a server system, a server cabinet, and an electrical connection method between them.

2. Description of Related Art

With the rapid development of various technologies, the market demand for server systems and servers is rising. The server has a high computing capability, and therefore is a core computing unit in a network system. When the servers are operating, the temperature of the entire system rises, and fans are needed to dissipate heat. However, when the power source electrically connected to the fans encounters problems, the fans stop operating, and the performance of the servers is affected as a result of the rise in heat. Thus, a new type of server system and server cabinet is needed to avoid this problem.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of an embodiment of a server system.

FIG. 2 is a schematic view showing the electrical connections of the server system of FIG. 1.

FIG. 3 is a flowchart of an embodiment of an electrical connection method.

### DETAILED DESCRIPTION

Embodiments of the present disclosure are now described in detail, with reference to the accompanying drawings.

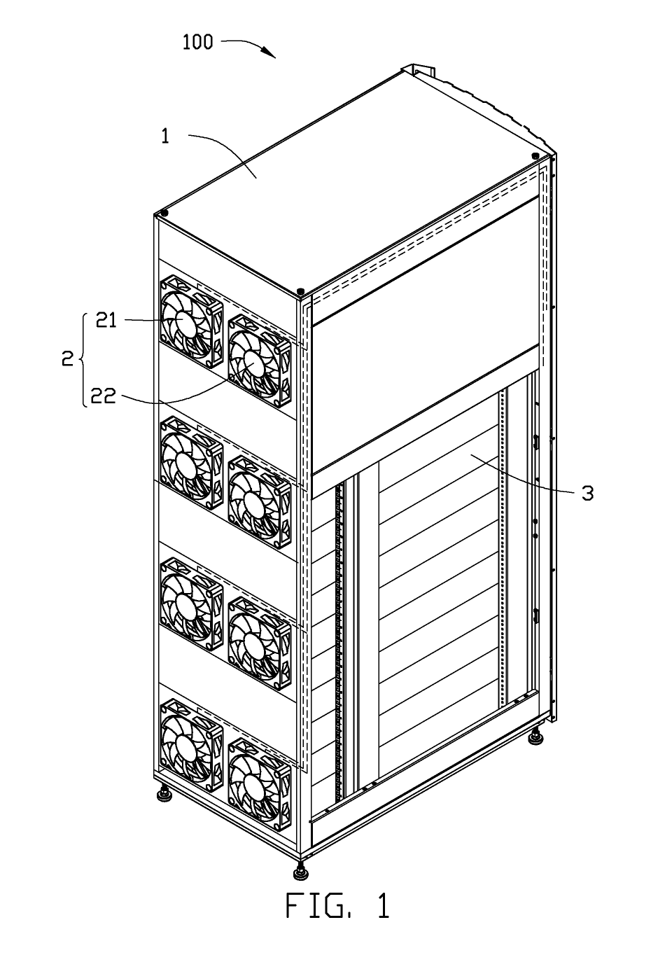

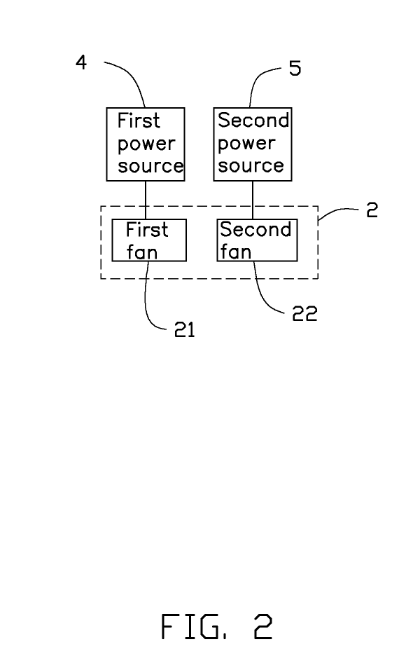

FIGS. 1-2 show an embodiment of a server system 100. The server system 100 includes a rack assembly 1, a number of fan groups 2, a number of servers 3, a first power source 4, and a second power source 5. The rack assembly 1, the fan groups 2, the first power source 4, and the second power source 5 cooperatively constitute a server cabinet (not labeled). The servers 3 are accommodated in the rack assembly 1. The number of fan groups 2 in one embodiment is four.

The fan groups 2 are coupled to a rear side of the rack assembly 1. Each fan group 2 includes a first fan 21 and a second fan 22 arranged side by side. The first fans 21 and the second fans 22 cooperatively provide horizontal airflow to dissipate heat generated by the servers 3. The first fans 21 are electrically connected to the first power source 4, and the second fans 22 are electrically connected to the second power source 5. In the embodiment, the first fans 21 are substantially vertically aligned with each other, and the second fans 22 are substantially vertically aligned with each other.

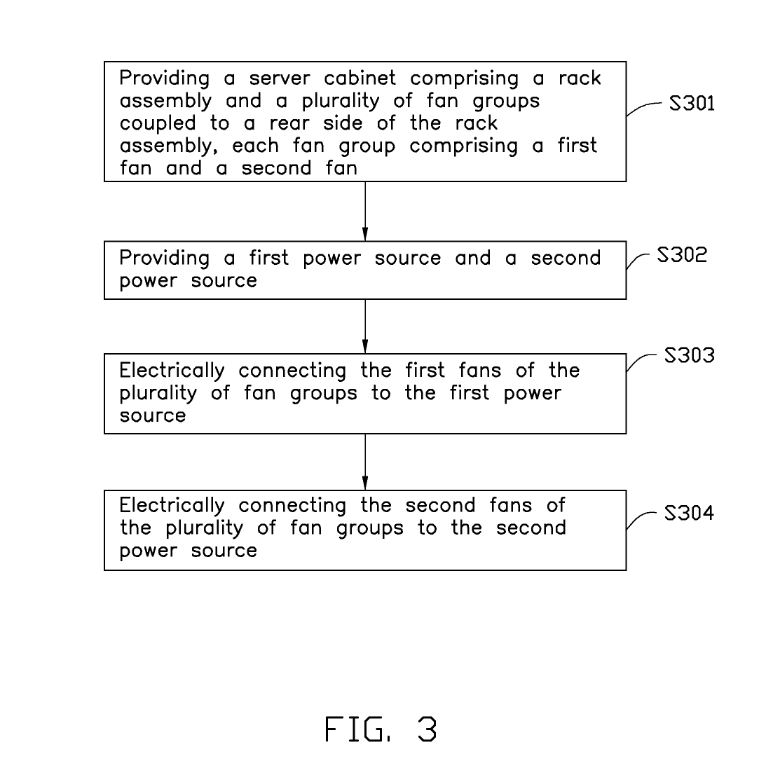

FIG. 3 also shows a flowchart of an embodiment of an electrical connection method.

In step S301, a rack assembly 1 and a number of fan groups 2 coupled to a rear side of the rack assembly 1 is provided. Each fan group 2 includes a first fan 21 and a second fan 22.

In step S302, a first power source 4 and a second power source 5 is provided.

In step S303, the first fans 21 are electrically connected to the first power source 4.

In step S304, the second fans 22 are electrically connected to the second power source 5.

If either the first power source 4 or the second power source 5 breaks down, the other power source 4 or 5 will still operate normally to allow the first fans 21 or the second fans 22 to continue to provide horizontal airflow, thereby allowing the servers 3 to operate normally for a period. Thus, the broken power source can be repaired or replaced in this period without affecting the operation of the servers 3.

While various embodiments have been described and illustrated, the disclosure is not to be constructed as being limited thereto. Various modifications can be made to the embodiments by those skilled in the art without departing from the true spirit and scope of the disclosure as defined by the appended claims.

What is claimed is:

1. A server cabinet comprising:
a rack assembly to accommodate a plurality of servers;
a plurality of fan groups coupled to a rear side of the rack assembly to provide horizontal airflow for dissipating heat generated by the plurality of servers, each fan group comprising a first fan and a second fan;
a first power source electrically connected to the first fan of each fan group; and
a second power source electrically connected to the second fan of each fan group.

2. The server cabinet as described in claim 1, wherein the first fans of the fan groups are substantially vertically aligned with each other, and the second fans of the fan groups are substantially vertically aligned with each other.

3. A server system comprising:
a plurality of servers; and
a server cabinet comprising:
a rack assembly accommodating the plurality of servers;
a plurality of fan groups coupled to a rear side of the rack assembly to provide horizontal airflow for dissipating heat generated by the plurality of servers, each fan group comprising a first fan and a second fan;
a first power source electrically connected to the first fan of each fan group; and
a second power source electrically connected to the second fan of each fan group.

4. The server system as described in claim 3, wherein the first fans of the plurality of fan groups are substantially vertically aligned with each other, and the second fans of the plurality of fan groups are substantially vertically aligned with each other.

5. An electrical connection method comprising:
providing a server cabinet comprising a rack assembly and a plurality of fan groups coupled to a rear side of the rack assembly, each fan group comprising a first fan and a second fan;
providing a first power source and a second power source;
electrically connecting the first fans of the plurality of fan groups to the first power source; and
electrically connecting the second fans of the plurality of fan groups to the second power source.
